(19) United States
(12) Patent Application Publication
(10) Pub. No.: US 2007/0004093 A1
(43) Pub. Date: Jan. 4, 2007

(54) METHOD OF FABRICATING A HIGH-DENSITY LEAD ARRANGEMENT PACKAGE STRUCTURE

(75) Inventor: Jeffrey Lien, Taipei (TW)

Correspondence Address: OPTIMUM CARE INTERNATIONAL TECH. INC., P.O. BOX 108-00403, TAIPEI, TW

(73) Assignee: OPTIMUM CARE INTERNATIONAL TECH. INC., Taipei (TW)

(21) Appl. No.: 11/530,036

(22) Filed: Sep. 8, 2006

Related U.S. Application Data
(63) Continuation-in-part of application No. 10/959,203, filed on Oct. 7, 2004, now abandoned.

(51) Int. Cl. H01L 21/60

(52) U.S. Cl. 438/123; 438/617; 438/124

(57) ABSTRACT

A method of fabricating a high-density lead arrangement package structure is disclosed. The first process of the packaging structure is packaging a chip, a plurality of leads and a plurality of metallic bonding wires by encapsulant such that conducting surfaces are formed at lower surfaces of the leads. The second process of the packaging structure is selectively forming insulation portions on the conducting surfaces of the leads according to the position of contact points on a circuit board. Thus, the overall fabrication cost of the chip package may be effectively reduced. Furthermore, the process of the packaging structure of the present invention is simple and is capable of increasing both the production yield and the reliability of the chip package device.

This application is a Continuation-In-Part of my patent application, Ser. No. 10/959,203, filed on Oct. 7, 2004.

### BACKGROUND OF THE INVENTION

1. Field of the Invention

This invention is related to a method of fabricating a high-density lead arrangement package structure, and more particularly to a method of fabricating the insulation portions on the conducting surfaces of the leads according the position of the contact points on the circuit board after the packaging of the chip.

2. Description of the Related Art

The current development trend of electronic products is not only for being lighter, thinner, shorter and smaller, but also for multi-functional, larger storage capacity, faster operation speed and smaller size. Presently, there is hardly an electronic product with a single function. The internal functional chips are designed smaller, microminiaturized, lighter and higher density than before. Accordingly, the arrangement of chips must be highly density and require a large number of leadframe and metallic bonding wires to connect the chip to the circuit board for transmitting numerous signals with high speed. Correspondingly, the distance between the chip and the mounted leadframe is congested/crowded, and the welding job for positioning the lead of the leadframe to the circuit board can be extremely difficult.

The leadframe serves as a bridge for connecting the chip and the circuit board and is an essential electronic component in the packaging process. The leadframe may be fabricated by using a stamping or etching process. Referring to FIGS. 11 and 12, when connecting a chip A to a leadframe B, a large number of leads B1 are required. Besides, for packaging, the leads B1 are required to have dented portions B11 formed on the bottom portion thereof for filling an encapsulant C to encapsulate the chip A and leadframe B. The dented portions B11 may be formed by an etching or stamping process. Each lead B1 comprises a protrusion B12 formed on the non-etched or non-flushed part thereof, and a bottom portion of the protrusion B12 may serve as a conducting surface B121 for welding to a circuit board. The protrusions B12 of the leads B1 are positioned in staggered arrangement as shown in FIG. 12 so that the spreading of the solder material may be avoided to undesirably electrically connect between the neighboring leads B1. However, the above conventional design has the following defects.

The leads B1 of the leadframe B have the dented portions B11 and the protrusions B12 by the etching or stamping process. In order to avoid spreading the excess solder material between the neighboring leads B1, the protrusions B12 of the leads B1 are formed in staggered arrangement. But after completing the fabrication of the leadframe B, the microminiaturized leads B1 has to be rearranged in a manner to position the protrusions B12 in staggered arrangement. Thus, the overall packaging process is too complicated and inconvenient.

If there are any changes in the contact points on the circuit board, the leads B1 must be etching or stamping again to create the corresponding protrusions B12 for the contact points on the circuit board. Accordingly, the cost of the molds and fabrication are substantially increased. Therefore, how to overcome the above defects of the conventional art is an important issue for the manufacturers in the field.

### SUMMARY OF THE INVENTION

Accordingly to an aspect of the present invention, a first process and a second process of the packaging structure are provided. The first process of the packaging structure is adopted for packaging the chip, the metallic bonding wires and the leads, and the conducting surfaces of the leads can be formed at the lower surfaces thereof and parts of the conducting surfaces are not packaged by the encapsulant. The second process of the packaging structure is adopted for selectively forming the insulation portions on the conducting surfaces not packaged by the encapsulant. This advantageous is that the second process of the packaging structure may be performed after confirming the position of the contact points on the circuit board or in a situation when the position of contact points on the circuit board is changed, so that the arrangement of the insulation portions on the conducting surfaces of the leads may be correspondingly changed. Thus, the process of the packaging structure may precisely and promptly implement while changing the position of the contact points on the circuit board. Thus, the fabrication cost may be effectively reduced, and the production yield may be effectively increased and reliability of the package device may be effectively promoted.

According to another aspect of the present invention, because the insulation portions formed on the conducting surfaces of the leads may be in staggered arrangement and the length of the insulation portions on the conducting surfaces of the leads are longer than the length of the conducting surfaces not covered by the insulation portions, an overlapped section is formed in the central region of the insulation portions on the conducting surfaces of the leads. This arrangement may be effective in preventing the spreading of the high temperature liquid-solder material on the conducting surfaces of the leads during the soldering/reflow process so that undesirable electrical connection (short circuit) between the neighboring leads may be effectively prevented. Accordingly, poor signal transmission quality can be effectively avoided. Furthermore, defects occurring due to poor welding of the chip to the circuit board may be effectively reduced.

### BRIEF DESCRIPTION OF THE DRAWING

FIG. 1 is a sectional side view showing before packaging according to an embodiment of the present invention.

FIG. 2 is a sectional side view showing after packaging according to an embodiment of the present invention.

FIG. 3 is a sectional side view showing the insulation portions formed on the conducting surfaces of the leads according to an embodiment of the present invention.

FIG. 4 is a top view showing the arrangement of the insulation portions formed on the conducting surfaces of the leads according to an embodiment of the present invention.

FIG. 5 is a sectional side view showing the insulation portions formed on the conducting surfaces of the leads according to another embodiment of the present invention.

FIG. 6 is a top view showing the arrangement of the insulation portions formed on the conducting surfaces of the leads according to another embodiment of the present invention.

FIG. 7 is a sectional side view showing the insulation portions formed on the conducting surfaces of the leads according to another embodiment of the present invention.

FIG. 8 is a top view the arrangement of the insulation portions formed on the conducting surfaces according to another embodiment of the present invention.

FIG. 9 is a sectional side view showing the insulation portions formed on the conducting surfaces of the leads according to another embodiment of the present invention.

FIG. 10 is a top view showing the arrangement of the insulation portions formed on the conducting surfaces of the leads according to another embodiment of the present invention.

FIG. 11 is a sectional side view of a conventional chip package.

FIG. 12 is a top view of the conventional chip package.

### DESCRIPTION OF THE INVENTION

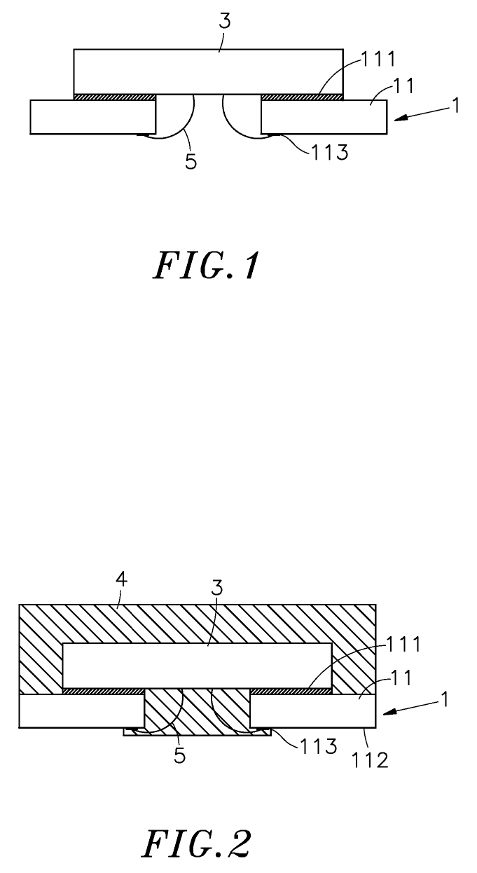

Referring to FIG. 1, 2, 3 and 4, a high-density lead arrangement package structure of the present invention for mounting a chip 3 is shown comprised of a leadframe 1 and a plurality of leads 11 electrically connected to an external circuit.

The chip 3 may be mounted on the right and left sides of the leadframe 1, and the numbers of leads 11 corresponding to the position or the number of contact points on a circuit board may form in rectangular blocks. An upper surface of each lead 11 serves as a carrying surface 111 on which the chip 3 may be attached by using suitable glue, and a lower surface of each lead 11 serves as a conducting surface 112 for electrically connecting to the contact points on the circuit board.

After attaching the chip 3 on the carrying surfaces 111 of the leads 11, a part of conducting points 31 on the chip 3, which never bind to the carrying surfaces 111, are electrically connected to conducting points 113 located at the conducting surfaces 112 of the leads 11 by using metallic bonding wires 5, as shown in FIG. 1. Next, the chip 3, the metallic bonding wires 5 and the leads 11 are encapsulated by using an encapsulant 4, wherein the conducting surface 112 of each lead 11 is partially encapsulated by the encapsulant 4, as shown in FIG. 2. Thus, the first process of the packaging structure according to the present invention is completed.

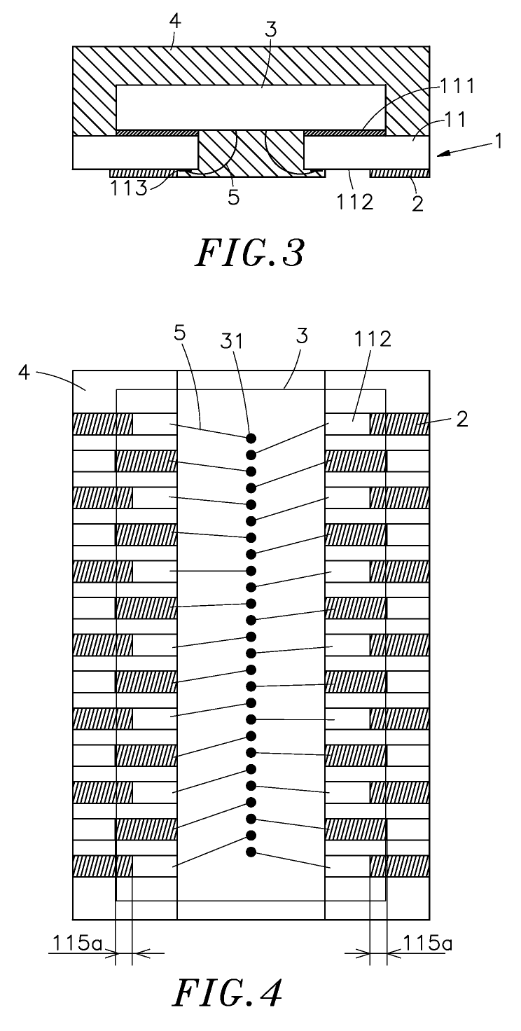

Furthermore, after encapsulating the chip 3 and the leadframe 1, insulation portions 2 are selectively formed on the exposed conducting surfaces 112 of the leads 11, as shown in FIG. 3. Thus, the second process of the packaging structure according to the present invention is completed. According to the position of the contact points on the circuit board, a parts of the conducting surfaces 112 of the leads 11 can be covered by the insulation portions 2, and other parts of the conducting surfaces 112 not covered by the insulation portions 2 are electrically connected to the contact points of the circuit board. And the insulation portions 2 on the conducting surfaces 112 of the leads 11 are in staggered arrangement, as shown in FIG. 4. Because the length of the insulation portion 2 formed on the conducting surface 112 of each lead 11 is longer than the length of the conducting surface 112 not covered by the insulation portion 2 and the insulation portion 2 on the conducting surface 112 of each lead 11 is in staggered arrangement, an overlapped section 115a can be formed on a central region of the insulation portion 2 on the conducting surface 112. Thus, the overlapped sections 115a on the central region of the conducting surfaces 112 can prevent the spreading of the high temperature liquid-solder material on the conducting surfaces 112 of the leads 11 during the soldering/reflow process so that undesirable electrical connection (short circuit) between the neighboring leads 11 may be effectively prevented.

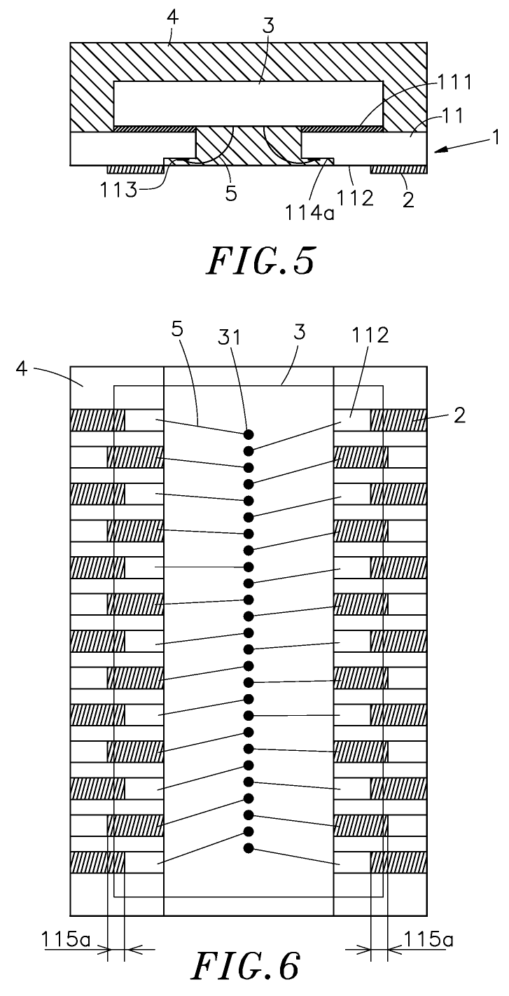

Referring to FIG. 5 and 6, an etching or stamping process may be performed on the conducting surface 112 of each lead 11 of the leadframe 1 to form a dented portion 114a. After connecting the leads 11 to the chip 3 by using the metallic bonding wires 5, the encapsulant 4 is applied to fill the dented portions 114a and encapsulates the metallic bonding wires 5 positioned in the dented portions 114a at the same time such that the bottom side of the encapsulant 4 and the conducting surfaces 112 of the leads 11 are in the same plane. Thus, the overall height of the chip package of the present invention may be reduced. After packaging the chip 3, the insulation portions 2 may be selectively formed on the exposed conducting surfaces 112 of the leads 11 according to the positions of the contact points on the circuit board so that the insulation portions 2 on the conducting surfaces 112 may be in staggered arrangement.

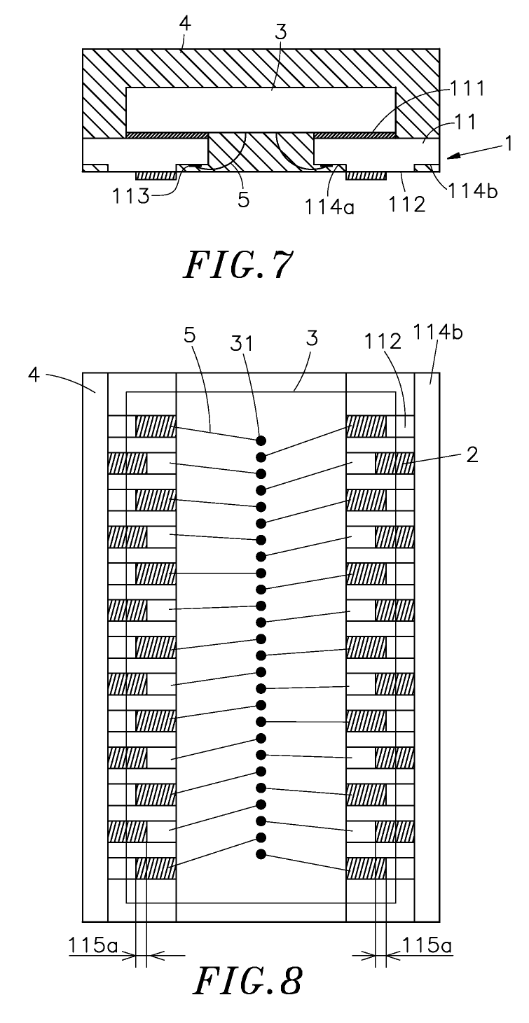

Furthermore, referring to FIG. 7 and 8, except for the dented portions 114a, a dented portions 114b may be formed by performing an etching or stamping process on another side of the leads 11 opposite to the dented portion 114a. The dented portions 114b may allow easy filling of the encapsulant 4 to encapsulate the chip 3, the metallic bonding wire 5 and the leads 11. Furthermore, after packaging the chip 3, the insulation portions 2 may be selectively formed on the exposed conducting surfaces 112 of the leads 11 according to the positions of the contact points on the circuit board so that the insulation portions 2 on the conducting surfaces 112 may be in staggered arrangement.

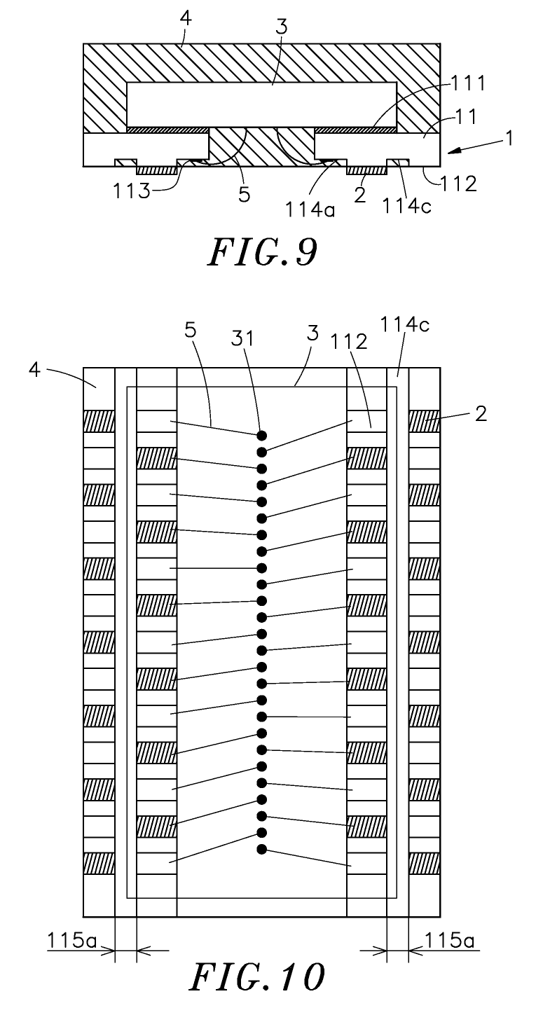

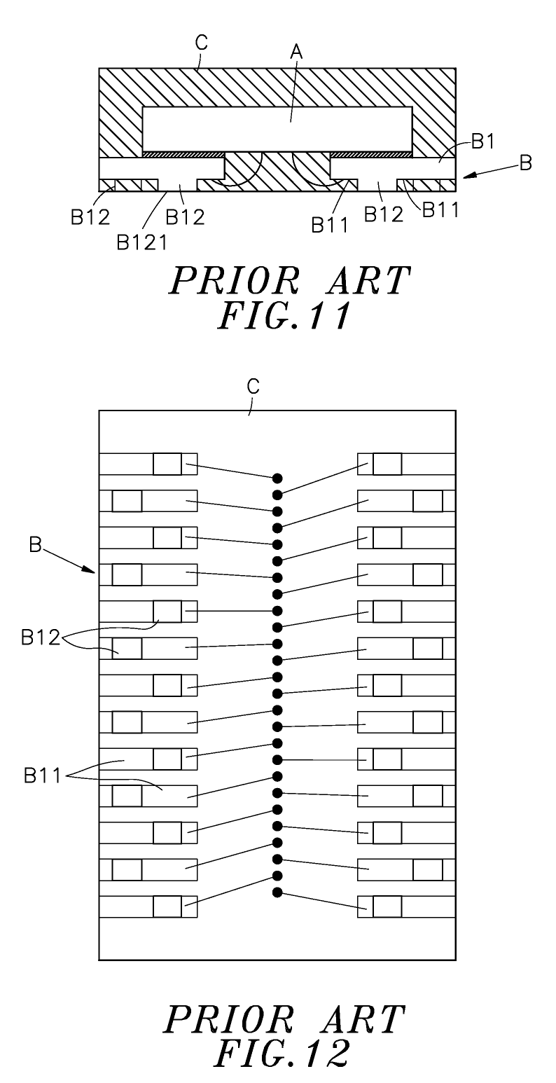

Referring to FIG. 9 and 10, except for the dented portions 114a, a dented portion 114c may be formed by performing an etching or stamping process at a central region of the leads 11 to divide the conducting surface 112 into two parts. Thus, the insulation portions 2 formed on the conducting surfaces 112 of the leads 11 may be alternatively arranged to prevent the spreading of the high temperature liquid-solder material on the conducting surfaces 112 of the leads 11 during the soldering/reflow process.

Furthermore, the insulation portions 2 may be comprised of an insulating film, a glue drop or a screen-printing. After packaging the chip 3 and leadframe 1 by the encapsulant 4, the second process of the packing structure is applied to form the insulation portions 2 on the conducting surface 112 not covered by the encapsulant 4. It should be noted that the above description is merely for illustrating the embodiments of the present invention and is not intended for limiting the scope of the present invention, and therefore any obvious modification of the above structure or process would be construed to be within the scope of the present invention.

Accordingly, the present invention has at least the following advantages.

1. After packaging the chip 3, the metallic bonding wire 5 and the leads 11 of the leadframe 1 by using the encapsulant 4 in the first process of the packing structure, the lower surfaces of the leads 11 not packaged by the encapsulant 4 serves as the conducting surfaces 112. In the second process of the packing structure the insulation portions 2 are adopted for selectively forming on the conducting surfaces 112 according to the position of the contact points on the circuit board to separate a zone for electrically connecting the leadframe 1 to the contact points on the circuit board. Accordingly, it is possible to arrange the insulation portions 2 on the conducting surfaces 112 of the leads 11 according to the position of the contact points on the circuit board. Thus, the disadvantage of the conventional art, which requires the rework or replace the leads of the leadframe when the contact points on the circuit board are changed, can be avoided. Thus, the overall fabrication cost of the chip package may be effectively reduced. Furthermore, the process of the present invention is simple and is capable of increasing both the production yield and the reliability of the chip package device.

2. Because the insulation portions 2 on the conducting surfaces 112 of the leads 11 are in staggered arrangement and the length of the insulation portions 2 is longer than the length of the conducting surface 112 not covered by the insulation portion 2, a overlapped section 115a is formed in the central region of the insulation portions 2 on the conducting surface 112. This arrangement would effectively prevent the spreading of the high temperature liquid-solder material on the conducting surfaces 112 of the leads 11 during the soldering/reflow process so that undesirable electrical connection (short circuit) between the neighboring leads 11 may be effectively prevented. Accordingly, signal transmission quality may be effectively promoted, and defects due to poor connection of the chip 3 to the circuit board may be effectively reduced.

Therefore, after packaging the leadframe 1 and the chip 3 by the encapsulant 4 in the first process of the packaging structure, the lower surfaces of the leads 11 of the leadframe 1 not packaged by the encapsulant 4 are formed the conducting surfaces 112. Next, in the second process of the packaging structure the insulation portion 2 may selectively form on the exposed conducting surfaces 112 of the leads 11 according to the position of the contact points on the circuit board. The insulation portions 2 on the conducting surfaces 112 of the leads 11 may be in staggered arrangement and an overlapped section 115a is formed in the central region of the insulation portions 2 on the conducting surfaces 112. This arrangement of the insulation portions 2 may effectively prevent the spreading of the high temperature liquid-solder material on the conducting surfaces 112 of the leads 11 during the soldering/reflow process so that undesirable electrical connection (short circuit) between the neighboring leads 11 may be effectively prevented. Furthermore, the insulation portion 2 of the present invention described above may be applied in the SOP, QFN, QFP and PBGA chip package. It should be noted that the above description is merely for illustrating the embodiments of the present invention and is not intended for limiting the scope of the present invention, and therefore any obvious modification of the above structure or process would be construed to be within the scope of the present invention.

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations in which fall within the spirit and scope of the included claims. All matters set forth herein or shown in the accompanying drawings are to be interpreted in an illustrative and non-limiting sense.

What the invention claimed is:

1. A method of fabricating a high-density lead arrangement package structure, comprising
providing a chip package, wherein said chip package comprises a leadframe having a plurality of leads, a chip and a plurality of metallic bonding wires connecting said leads to said chip, and an encapsulant is adopted for packaging said chip, said metallic bonding wires and said leads such that a lower surface of each lead not packaged by said encapsulant is formed a conducting surface; and
forming an insulation portion, wherein said insulation portion can be positioned on said conducting surface not packaged by said encapsulant according to the position of contact points on a circuit board, and said insulation portions on said conducting surfaces of said leads are in staggered arrangement.

2. The method of fabricating the high-density lead arrangement package structure as claimed in claim 1, wherein a length of said insulation portion on said conducting surface of each lead is longer than a length of said conducting surface not covered by said insulation portions so that a overlapped portion is formed in a central region of said insulation portions on said conducting surface to avoid spreading of high temperature liquid-solder material on said conducting surfaces of said leads during the soldering/reflow process.

3. The method of fabricating the high-density lead arrangement package structure as claimed in claim 1, wherein said conducting surfaces of said leads comprise dented portions for filling said encapsulant such that said conducting surfaces and a bottom surface of said encapsulant are in the same plane.

4. The method of fabricating the high-density lead arrangement package structure as claimed in claim 3, wherein said dented portions of said leads are formed by performing a stamping process.

5. The method of fabricating the high-density lead arrangement package structure as claimed in claim 3, wherein said dented portions of said leads are formed by performing an etching process.

6. The method of fabricating the high-density lead arrangement package structure as claimed in claim 1, wherein said insulation portion is comprised of an insulating film, a glue drop or a screen printing.
